(19) United States
(12) Patent Application Publication
(10) Pub. No.: US 2025/0031340 A1
(43) Pub. Date: Jan. 23, 2025

(54) IMMERSION LIQUID COOLING SYSTEM

(71) Applicant: Hebei Qinhuai Data Co., Limited., Zhangjiakou City (CN)

(72) Inventor: Binghua ZHANG, Zhangjiakou City (CN)

(21) Appl. No.: 18/776,035

(22) Filed: Jul. 17, 2024

(30) Foreign Application Priority Data
Jul. 20, 2023 (CN) 202310894678.8

(51) Int. Cl. H05K 7/20

(52) U.S. Cl. CPC H05K 7/20236; H05K 7/20272; H05K 7/20781

(57) ABSTRACT

The present disclosure discloses an immersion liquid cooling system, including a cooling water circulation pump which is provided with an outlet pipeline of the cooling water circulation pump, where the cooling water circulation pump is provided with a cooling water pump inlet pipeline, and a closed cooling tower is arranged on the cooling water pump inlet pipeline.

### CROSS REFERENCE TO RELATED APPLICATION

This application claims priority to Chinese Patent Application No. 202310894678.8, titled “IMMERSION LIQUID COOLING SYSTEM” and filed to the China National Intellectual Property Administration on Jul. 20, 2023, the entire contents of which are incorporated herein by reference.

### TECHNICAL FIELD

The present disclosure relates to the field of liquid cooling, and more particularly, to an immersion liquid cooling system.

### BACKGROUND

Existing servers and data centers use a circulating air cooling method to cool devices such as servers by means of cold air supplied by refrigeration units. With the development of the industry and the increase in power density, cooling capacity of the circulating air cooling method is also approaching its limit, which cannot meet cooling requirements for arrangement of high power density computer rooms.

With the rapid development of cloud computing, demands for server performance is becoming increasingly high. As the server performance improves, power consumption also increases, and cabinet power consumption increases exponentially. In recent years, the power density of cabinets in the data centers has increased by several times.

Therefore, based on the above limitations, it is necessary to provide a new cooling method to cool the servers in the computer rooms.

### SUMMARY

The present disclosure provides an immersion liquid cooling system, and is aimed at solving a problem of failure in meeting cooling requirements for arrangement of high power density computer rooms.

According to embodiments of the present disclosure, there is provided an immersion liquid cooling system, which includes a cooling water circulation pump, where the cooling water circulation pump is provided with an outlet pipeline of the cooling water circulation pump, and the cooling water circulation pump is provided with a cooling water pump inlet pipeline. The cooling water pump inlet pipeline is provided with a closed cooling tower, and the closed cooling tower is provided with an inlet pipeline of the closed cooling tower. The inlet pipeline of the closed cooling tower is provided with a first water side inlet pipeline, and the first water side inlet pipeline is provided with a first immersion liquid heat exchanger. The first immersion liquid heat exchanger is provided with an inlet pipeline of the first immersion liquid heat exchanger, and the inlet pipeline of the first immersion liquid heat exchanger is provided with a server cluster box body. The server cluster box body is internally provided with an immersion liquid, and the server cluster box body is internally provided with an immersion liquid distributor. The first immersion liquid heat exchanger is provided with an inlet pipeline of a first immersion liquid circulation pump, and the inlet pipeline of the first immersion liquid circulation pump is provided with the first immersion liquid circulation pump. The inlet pipeline of the closed cooling tower is provided with a second water side inlet pipeline, and the second water side inlet pipeline is provided with a second immersion liquid heat exchanger. The second immersion liquid heat exchanger is provided with an inlet pipeline of the second immersion liquid heat exchanger, and the inlet pipeline of the second immersion liquid heat exchanger is connected to the server cluster box body. The second immersion liquid heat exchanger is provided with an inlet pipeline of a second immersion liquid circulation pump, and the inlet pipeline of the second immersion liquid circulation pump is provided with the second immersion liquid circulation pump.

In the immersion liquid cooling system of the present disclosure, a server cluster is arranged inside the server cluster box body, and the server cluster comes into contact with the immersion liquid. By designing the server cluster coming into contact with the immersion liquid, heat exchange can be carried out on the server cluster.

In the immersion liquid cooling system of the present disclosure, the first immersion liquid circulation pump is provided with an outlet pipeline of the first immersion liquid circulation pump, and the outlet pipeline of the first immersion liquid circulation pump is connected to the server cluster box body. By designing the outlet pipeline of the first immersion liquid circulation pump, liquid circulation can be carried out on the immersion liquid.

In the immersion liquid cooling system of the present disclosure, the second immersion liquid circulation pump is provided with an outlet pipeline of the second immersion liquid circulation pump, and the outlet pipeline of the second immersion liquid circulation pump is connected to the server cluster box body. By designing the outlet pipeline of the second immersion liquid circulation pump, liquid circulation can be carried out on the immersion liquid.

In the immersion liquid cooling system of the present disclosure, a first cooling water pipeline is arranged on the outlet pipeline of the cooling water circulation pump, and the first cooling water pipeline is connected to the first immersion liquid heat exchanger. By designing the first cooling water pipeline, heat exchange can be carried out between the cooling water and the first immersion liquid heat exchanger.

In the immersion liquid cooling system of the present disclosure, a second cooling water pipeline is arranged on the outlet pipeline of the cooling water circulation pump, and the second cooling water pipeline is connected to the second immersion liquid heat exchanger. By designing the second cooling water pipeline, heat exchange can be carried out between the cooling water and the second cooling water pipeline.

The technical solutions provided by the embodiments of the present disclosure may include following beneficial effects.

By using an immersion liquid to cool a server, heat dissipation efficiency of the server in a data center computer room is improved on the whole, and a bottleneck problem, for the server in the data center computer room, of using a mechanical refrigeration system for air cooling is solved. High-power heat dissipation efficiency, high-density layout, and operational reliability of the server in the data center computer room are increased. A problem of compatibility between the server in the data center computer room and the immersion cooling liquid is solved. The use of the mechanical refrigeration system for air cooling is saved, and area occupied by the data center is reduced, thus meeting demands for arrangement of more servers. Furthermore, by fully utilizing natural cooling sources, a problem of higher energy consumption for heat dissipation and cooling in the data center computer room is solved.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of an overall structure according to the present disclosure.

Reference numerals in the accompanying drawings:
outlet pipeline 1 of a cooling water circulation pump; cooling water circulation pump 2; cooling water pump inlet pipeline 3; outlet pipeline 4 of a first immersion liquid circulation pump; first immersion liquid circulation pump 5; inlet pipeline 6 of the first immersion liquid circulation pump; first immersion liquid heat exchanger 7; first cooling water pipeline 8; inlet pipeline 9 of the first immersion liquid heat exchanger; first water side inlet pipeline 10; closed cooling tower 11; inlet pipeline 12 of the closed cooling tower; second water side inlet pipeline 13; second immersion liquid heat exchanger 14; inlet pipeline 15 of the second immersion liquid heat exchanger; immersion liquid 16; server cluster 17; server cluster box body 18; inlet pipeline 19 of a second immersion liquid circulation pump; second immersion liquid circulation pump 20; outlet pipeline 21 of the second immersion liquid circulation pump; immersion liquid distributor 22; and second cooling water pipeline 23.

### DETAILED DESCRIPTION

Technical solutions in the embodiments of the present disclosure will be described clearly and completely below, in conjunction with the accompanying drawings in the embodiments of the present disclosure. Apparently, the described embodiments are some but not all of the embodiments of the present disclosure. All other embodiments obtained by a person of ordinary skill in the art based on the embodiments of the present disclosure without creative efforts shall fall within the protection scope of the present disclosure.

It should also be understood that the terms used in this specification of the present disclosure are only for the purpose of describing particular embodiments and are not intended to limit the present disclosure. As used in the specification and the appended claims of the present disclosure, the singular forms of “a”, “an” and “the” may be intended to include the plural forms, unless the context clearly indicates otherwise.

It should also be further understood that the term “and/or” used in the specification and the appended claims of the present disclosure refers to any combination of one or more of the relevantly listed items and all possible combinations, and includes these combinations.

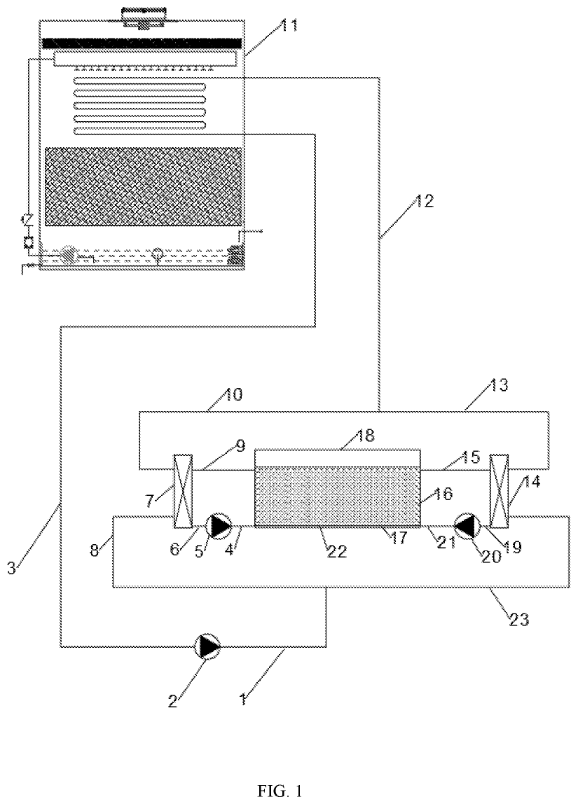

Referring to FIG. 1, an immersion liquid cooling system includes a cooling water circulation pump 2. The cooling water circulation pump 2 is provided with an outlet pipeline 1 of the cooling water circulation pump, and the cooling water circulation pump 2 is provided with a cooling water pump inlet pipeline 3. The cooling water pump inlet pipeline 3 is provided with a closed cooling tower 11, and the closed cooling tower 11 is provided with an inlet pipeline 12 of the closed cooling tower. The inlet pipeline 12 of the closed cooling tower is provided with a first water side inlet pipeline 10, and the first water side inlet pipeline 10 is provided with a first immersion liquid heat exchanger 7. A first cooling water pipeline 8 is arranged on the outlet pipeline 1 of the cooling water circulation pump, and the first cooling water pipeline 8 is connected to the first immersion liquid heat exchanger 7. By designing the first cooling water pipeline 8, the cooling water may exchange heat with the first immersion liquid heat exchanger 7.

Referring to FIG. 1, the first immersion liquid heat exchanger 7 is provided with an inlet pipeline 9 of the first immersion liquid heat exchanger, and the inlet pipeline 9 of the first immersion liquid heat exchanger is provided with a server cluster box body 18. The server cluster box body 18 is internally provided with an immersion liquid 16, which is a perfluorinated compound having characteristics of noninflammability, insulativity, and material compatibility. The server cluster box body 18 is internally provided with a server cluster 17, which comes into contact with the immersion liquid 16. By designing the server cluster 17 coming into contact with the immersion liquid 16, heat exchange can be carried out on the server cluster 17. The server cluster box body 18 is internally provided with an immersion liquid distributor 22. The first immersion liquid heat exchanger 7 is provided with an inlet pipeline 6 of a first immersion liquid circulation pump, and the inlet pipeline 6 of the first immersion liquid circulation pump is provided with the first immersion liquid circulation pump 5. The first immersion liquid circulation pump 5 is provided with an outlet pipeline 4 of the first immersion liquid circulation pump, and the outlet pipeline 4 of the first immersion liquid circulation pump is connected to the server cluster box body 18. By designing the outlet pipeline 4 of the first immersion liquid circulation pump, liquid circulation can be carried out on the immersion liquid 16.

Referring to FIG. 1, the inlet pipeline 12 of the closed cooling tower is provided with a second water side inlet pipeline 13, and the second water side inlet pipeline 13 is provided with a second immersion liquid heat exchanger 14. A second cooling water pipeline 23 is arranged on the outlet pipeline 1 of the cooling water circulation pump, and the second cooling water pipeline 23 is connected to the second immersion liquid heat exchanger 14. By designing the second cooling water pipeline 23, heat exchange can be carried out between the cooling water and the second cooling water pipeline 23. The second immersion liquid heat exchanger 14 is provided with an inlet pipeline 15 of the second immersion liquid heat exchanger, and the inlet pipeline 15 of the second immersion liquid heat exchanger is connected to the server cluster box body 18. The second immersion liquid heat exchanger 14 is provided with an inlet pipeline 19 of a second immersion liquid circulation pump, and the inlet pipeline 19 of the second immersion liquid circulation pump is provided with the second immersion liquid circulation pump 20. The second immersion liquid circulation pump 20 is provided with an outlet pipeline 21 of the second immersion liquid circulation pump, and the outlet pipeline 21 of the second immersion liquid circulation pump is connected to the server cluster box body 18. By designing the outlet pipeline 21 of the second immersion liquid circulation pump, liquid circulation can be carried out on the immersion liquid 16.

Specific implementation processes of the present disclosure are as follows. The immersion liquid cooling system includes the outlet pipeline 1 of the cooling water circulation pump, the cooling water circulation pump 2, the cooling water pump inlet pipeline 3, the closed cooling tower 11, the inlet pipeline 12 of the closed cooling tower, the first immersion liquid heat exchanger 7, the second immersion liquid heat exchanger 14, the first water side inlet pipeline 10, and the second water side inlet pipeline 13, to form a cooling water circulation system, which is used for dissipating heat from a server in a data computer room to outside by means of the closed cooling tower 11. An immersion liquid circulation system comprises the first immersion liquid heat exchanger 7, the second immersion liquid heat exchanger 14, the inlet pipeline 6 of the first immersion liquid circulation pump, the inlet pipeline 19 of the second immersion liquid circulation pump, the first immersion liquid circulation pump 5, the second immersion liquid circulation pump 20, the outlet pipeline 4 of the first immersion liquid circulation pump, the outlet pipeline 21 of the second immersion liquid circulation pump, the server cluster box body 18, the immersion liquid distributor 22, the server cluster 17, the immersion liquid 16 (the immersion liquid used in this example is perfluorinated compound, which has characteristics of noninflammability, insulativity, and material compatibility), the inlet pipeline 9 of the first immersion liquid heat exchanger, and the inlet pipeline 15 of the second immersion liquid heat exchanger. Heat exchange is carried out by means of the immersion liquid heat exchanger, such that heat generated by the server during operation is exchanged to the cooling water system.

In left-side operation, the immersion liquid cooling system includes the outlet pipeline 1 of the cooling water circulation pump, the cooling water circulation pump 2, the cooling water pump inlet pipeline 3, the closed cooling tower 11, the inlet pipeline 12 of the closed cooling tower, the first immersion liquid heat exchanger 7, and the first water side inlet pipeline 10, to form the cooling water circulation system, which is used for dissipating the heat from the server in the data computer room to outside by means of the closed cooling tower 11. The immersion liquid circulation system comprises the first immersion liquid heat exchanger 7, the inlet pipeline 6 of the first immersion liquid circulation pump, the first immersion liquid circulation pump 5, the outlet pipeline 4 of the first immersion liquid circulation pump, the server cluster box body 18, the immersion liquid distributor 22, the server cluster 17, the immersion liquid 16, and the inlet pipeline 9 of the first immersion liquid heat exchanger. Heat exchange is carried out by means of the immersion liquid heat exchanger, such that the heat generated by the server during operation is exchanged to the cooling water system.

In right-side operation, the immersion liquid cooling system includes the outlet pipeline 1 of the cooling water circulation pump, the cooling water circulation pump 2, the cooling water pump inlet pipeline 3, the closed cooling tower 11, the inlet pipeline 12 of the closed cooling tower, the second immersion liquid heat exchanger 14, and the second water side inlet pipeline 13, to form the cooling water circulation system, which is used for dissipating the heat from the server in the data computer room to outside by means of the closed cooling tower 11. The immersion liquid circulation system comprises the second immersion liquid heat exchanger 14, the inlet pipeline 19 of the second immersion liquid circulation pump, the second immersion liquid circulation pump 20, the outlet pipeline 21 of the second immersion liquid circulation pump, the server cluster box body 18, the immersion liquid distributor 22, the server cluster 17, the immersion liquid 16, and the inlet pipeline 15 of the second immersion liquid heat exchanger. Heat exchange is carried out by means of the immersion liquid heat exchanger, such that the heat generated by the server during operation is exchanged to the cooling water system.

In integral operation, the immersion liquid cooling system includes the outlet pipeline 1 of the cooling water circulation pump, the cooling water circulation pump 2, the cooling water pump inlet pipeline 3, the closed cooling tower 11, the inlet pipeline 12 of the closed cooling tower, the first immersion liquid heat exchanger 7, the second immersion liquid heat exchanger 14, the first water side inlet pipeline 10, and the second water side inlet pipeline 13, to form the cooling water circulation system, which is used for dissipating the heat from the server in the data computer room to outside by means of the closed cooling tower 11. The immersion liquid circulation system comprises the first immersion liquid heat exchanger 7, the second immersion liquid heat exchanger 14, the inlet pipeline 6 of the first immersion liquid circulation pump, the inlet pipeline 19 of the second immersion liquid circulation pump, the first immersion liquid circulation pump 5, the second immersion liquid circulation pump 20, the outlet pipeline 4 of the first immersion liquid circulation pump, the outlet pipeline 21 of the second immersion liquid circulation pump, the server cluster box body 18, the immersion liquid distributor 22, the server cluster 17, the immersion liquid 16, the inlet pipeline 9 of the first immersion liquid heat exchanger, and the inlet pipeline 15 of the second immersion liquid heat exchanger. Heat exchange is carried out by means of the immersion liquid heat exchanger, such that the heat generated by the server during operation is exchanged to the cooling water system. By adjusting the immersion liquid cooling circulation pump, a required flow rate of the immersion liquid 16 is obtained to meet the heat dissipation requirements of the server cluster box body 18.

The preceding descriptions are merely specific embodiments of the present disclosure, but are not intended to limit the protection scope of the present disclosure. Any equivalent modifications or replacements easily conceivable to a person of skilled in the art within the technical scope disclosed in the present disclosure shall fall within the protection scope of the present disclosure. Therefore, the protection scope of the present disclosure shall be subject to that of the claims.

What is claimed is:

1. An immersion liquid cooling system comprising a cooling water circulation pump, wherein the cooling water circulation pump is provided with an outlet pipeline of the cooling water circulation pump, the cooling water circulation pump is provided with a cooling water pump inlet pipeline, the cooling water pump inlet pipeline is provided with a closed cooling tower, the closed cooling tower is provided with an inlet pipeline of the closed cooling tower, the inlet pipeline of the closed cooling tower is provided with a first water side inlet pipeline, the first water side inlet pipeline is provided with a first immersion liquid heat exchanger, the first immersion liquid heat exchanger is provided with an inlet pipeline of the first immersion liquid heat exchanger, the inlet pipeline of the first immersion liquid heat exchanger is provided with a server cluster box body, the server cluster box body is internally provided with an immersion liquid, the server cluster box body is internally provided with an immersion liquid distributor, the first immersion liquid heat exchanger is provided with an inlet pipeline of a first immersion liquid circulation pump, the inlet pipeline of the first immersion liquid circulation pump is provided with the first immersion liquid circulation pump, the inlet pipeline of the closed cooling tower is provided with a second water side inlet pipeline, the second water side inlet pipeline is provided with a second immersion liquid heat exchanger, the second immersion liquid heat exchanger is provided with an inlet pipeline of the second immersion liquid heat exchanger, the inlet pipeline of the second immersion liquid heat exchanger is connected to the server cluster box body, the second immersion liquid heat exchanger is provided with an inlet pipeline of a second immersion liquid circulation pump, and the inlet pipeline of the second immersion liquid circulation pump is provided with the second immersion liquid circulation pump.

2. The immersion liquid cooling system according to claim 1, wherein a server cluster is arranged inside the server cluster box body, and the server cluster comes into contact with the immersion liquid.

3. The immersion liquid cooling system according to claim 1, wherein the first immersion liquid circulation pump is provided with an outlet pipeline of the first immersion liquid circulation pump, and the outlet pipeline of the first immersion liquid circulation pump is connected to the server cluster box body.

4. The immersion liquid cooling system according to claim 1, wherein the second immersion liquid circulation pump is provided with an outlet pipeline of the second immersion liquid circulation pump, and the outlet pipeline of the second immersion liquid circulation pump is connected to the server cluster box body.

5. The immersion liquid cooling system according to claim 1, wherein a first cooling water pipeline is arranged on the outlet pipeline of the cooling water circulation pump, and the first cooling water pipeline is connected to the first immersion liquid heat exchanger.

6. The immersion liquid cooling system according to claim 1, wherein a second cooling water pipeline is arranged on the outlet pipeline of the cooling water circulation pump, and the second cooling water pipeline is connected to the second immersion liquid heat exchanger.
